(19) United States
(12) Patent Application Publication
(10) Pub. No.: US 2025/0201535 A1
(43) Pub. Date: Jun. 19, 2025

(54) PLASMA PROCESSING APPARATUS AND PLASMA PROCESSING METHOD

(71) Applicant: Tokyo Electron Limited, Tokyo (JP)

(72) Inventors: Sho OIKAWA, Miyagi (JP); Manabu ISHIKAWA, Miyagi (JP); Yuki KUMAGAI, Miyagi (JP); Hiroki SATO, Miyagi (JP); Takumi IMAHASHI, Miyagi (JP); Ryo KURODA, Tokyo (JP)

(73) Assignee: Tokyo Electron Limited, Tokyo (JP)

(21) Appl. No.: 19/070,689

(22) Filed: Mar. 5, 2025

Related U.S. Application Data
(63) Continuation of application No. PCT/JP2024/028529, filed on Aug. 8, 2024.

(30) Foreign Application Priority Data
Sep. 29, 2023 (JP) 2023-169430
Apr. 26, 2024 (JP) 2024-072408
May 17, 2024 (JP) 2024-080869

(51) Int. Cl. H01J 37/32

(52) U.S. Cl. CPC H01J 37/32642; H01J 37/32174; H01J 37/32715; H01J 37/32926; H01J 2237/2007; H01J 2237/334; H01J 2237/335

(57) ABSTRACT

A plasma processing apparatus includes a chamber, a substrate support in the chamber, a plasma generator, a bias power supply, an edge ring, a lifter, a switch, and a controller. At least one of the bias power supply or a radio-frequency power supply in the plasma generator is electrically coupled to a base in the substrate support. The lifter includes a conductive ring, a rod, an actuator, and a connector. The lifter raises and lowers the edge ring supported on the conductive ring. The connector electrically couples the conductive ring and the base. The switch changes between a first state in which the edge ring and the base are electrically coupled to each other and a second state in which the edge ring and the base are electrically disconnected from each other. The controller controls the switch.

### CROSS-REFERENCE TO RELATED APPLICATIONS

This application is a Continuation of PCT International Application No. PCT/JP2024/028529, filed on Aug. 8, 2024, which claims priority under 35 U.S.C. § 119 (a) to Japanese Patent Application No. JP 2023-169430, filed in on Sep. 29, 2023, Japanese Patent Application No. JP 2024-072408, filed in on Apr. 26, 2024 and Japanese Patent Application No. JP 2024-080869, filed in on May 17, 2024, all of which are hereby expressly incorporated by reference into the present application.

### FIELD

Exemplary embodiments of the disclosure relate to a plasma processing apparatus and a substrate processing system.

### BACKGROUND

A plasma processing apparatus is used to perform plasma processing on a substrate. The plasma processing apparatus includes a chamber and a substrate support. The substrate support is located in the chamber. The substrate support includes a base and an electrostatic chuck. The base is coupled to a bias power supply that generates an electrical bias to draw ions from plasma into the substrate. The electrostatic chuck supports the substrate and an edge ring to surround the substrate. Patent Literature 1 describes a plasma processing apparatus that raises and lowers the edge ring.

### CITATION LIST

### Patent Literature

Patent Literature 1: Japanese Unexamined Patent Application Publication No. 2020-113753

### BRIEF SUMMARY

### Technical Problem

The disclosure is directed to a technique for reducing wear of an edge ring.

### Solution to Problem

A plasma processing apparatus is described in one or more embodiments of the present application. The plasma processing apparatus includes a chamber, a substrate support, a plasma generator, a bias power supply, an edge ring, a lifter, a switch, and a controller. The substrate support is in the chamber. The substrate support includes a base and an electrostatic chuck on the base. The plasma generator includes a radio-frequency power supply to generate plasma in the chamber. The bias power supply generates an electrical bias to draw ions from the plasma into a substrate on the substrate support. At least one of the bias power supply or the radio-frequency power supply is electrically coupled to the base. The edge ring is conductive and surrounds the substrate on the substrate support. The lifter raises and lowers the edge ring. The lifter includes a conductive ring, a rod, an actuator, and a connector. The conductive ring is electrically coupled to the edge ring while supporting the edge ring placed on the conductive ring. The rod extends in a vertical direction below the conductive ring. The actuator raises and lowers the edge ring with the rod and the conductive ring. The connector electrically couples the conductive ring and the base. The switch switches between establishing (e.g., changing to or operating in) a first state in which the edge ring and the base are electrically coupled to each other and establishing a second state in which the edge ring and the base are electrically disconnected from each other. The controller controls the switch to switch between establishing the first state and establishing the second state.

### Advantageous Effects

The technique according to one or more embodiments of the present disclosure reduces wear of the edge ring.

### BRIEF DESCRIPTION OF DRAWINGS

FIG. 1 is a diagram of a plasma processing system with an example structure.

FIG. 2 is a diagram of a capacitively coupled plasma processing apparatus with an example structure.

FIG. 3 is a diagram of a substrate support and a lifter in one exemplary embodiment.

FIG. 4 is a diagram of a substrate support and a lifter in another exemplary embodiment.

FIG. 5 is a diagram of a switch and a sensor in the plasma processing apparatus according to one exemplary embodiment.

FIG. 6 is a diagram of a substrate processing system according to one exemplary embodiment.

FIG. 7 is a diagram of a substrate support and a lifter in still another exemplary embodiment.

FIG. 8 is a flowchart of a plasma processing method according to one exemplary embodiment.

FIG. 9 is a flowchart of a plasma processing method according to another exemplary embodiment.

FIG. 10 is a flowchart of a plasma processing method according to still another exemplary embodiment.

FIG. 11 is a block diagram of processing circuitry for performing computer-based operations described herein.

FIG. 12 is a diagram of a substrate support and a lifter in one exemplary embodiment.

FIG. 13 is a diagram of a substrate support and a lifter in still another exemplary embodiment.

FIG. 14 is a diagram of a substrate support and a lifter in still another exemplary embodiment.

FIG. 15 is a diagram of a substrate support and a lifter in still another exemplary embodiment.

FIG. 16 is a diagram of a substrate support and a lifter in still another exemplary embodiment.

FIG. 17 is a diagram of a substrate support and a lifter in still another exemplary embodiment.

FIG. 18 is a diagram of a substrate support and a lifter in still another exemplary embodiment.

FIG. 19 is a diagram of a substrate support and a lifter in still another exemplary embodiment.

FIG. 20 is a diagram of a substrate support and a lifter in still another exemplary embodiment.

### DETAILED DESCRIPTION

Exemplary embodiments will now be described in detail with reference to the drawings. In the drawings, like reference numerals denote like or corresponding components.

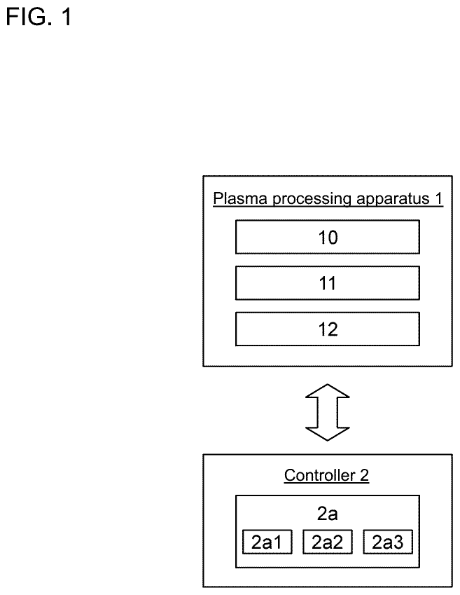

FIG. 1 is a diagram of a plasma processing system with an example structure. In one or more embodiments of the present disclosure, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas inlet for supplying at least one process gas into the plasma processing space and at least one gas outlet for discharging the gas from the plasma processing space. The gas inlet connects to a gas supply 20 (described later). The gas outlet connects to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be capacitively coupled plasma (CCP), inductively coupled plasma (ICP), electron cyclotron resonance (ECR) plasma, helicon wave plasma (HWP), or surface wave plasma (SWP). Various plasma generators including an alternating current (AC) plasma generator and a direct current (DC) plasma generator may be used. In one or more embodiments of the present disclosure, an AC signal (AC power) used in the AC plasma generator has a frequency in a range of 100 kHz to 10 GHz. Thus, the AC signal includes a radio-frequency (RF) signal and a microwave signal. In one or more embodiments of the present disclosure, the RF signal has a frequency in a range of 100 kHz to 150 MHz.

The controller 2 processes computer-executable instructions that cause the plasma processing apparatus 1 to perform various steps described in one or more embodiments of the disclosure. The controller 2 may control the components of the plasma processing apparatus 1 to perform the various steps described herein. In one or more embodiments of the present disclosure, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2al may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2al. The medium may be one of various storage media readable by the computer 2a, or a communication line connected to the communication interface 2a3. The processor 2al may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

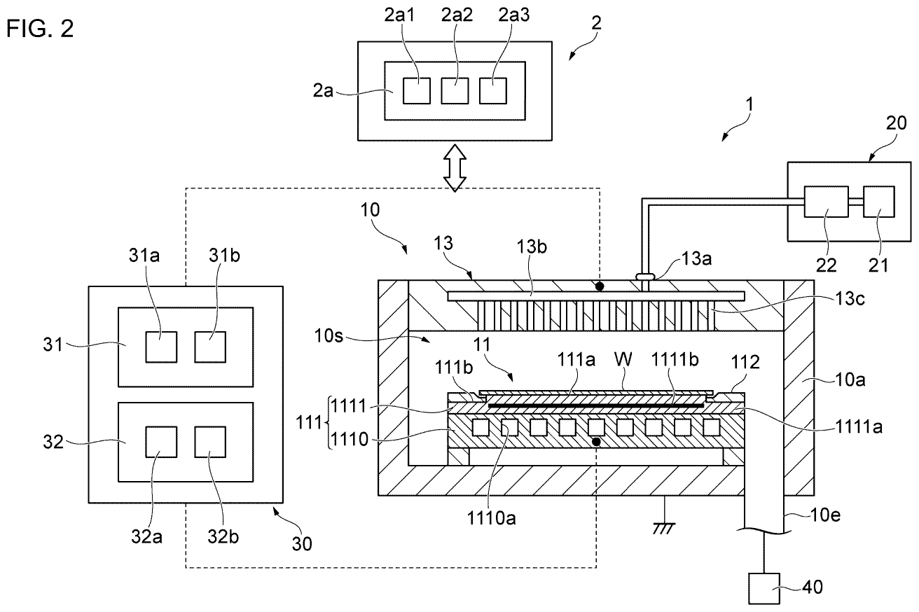

An example structure of a capacitively coupled plasma processing apparatus as an example of the plasma processing apparatus 1 will now be described. FIG. 2 is a diagram of the capacitively coupled plasma processing apparatus with an example structure.

The capacitively coupled plasma processing apparatus 1 includes the plasma processing chamber 10, the gas supply 20, a power supply 30, and the exhaust system 40. The plasma processing apparatus 1 also includes the substrate support 11 and a gas guide unit. The gas guide unit allows at least one process gas to be introduced into the plasma processing chamber 10. The gas guide unit includes a shower head 13. The substrate support 11 is located in the plasma processing chamber 10. The shower head 13 is located above the substrate support 11. In one or more embodiments of the present disclosure, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a body 111 and a ring assembly 112. The body 111 includes a central area 111a for supporting a substrate W and an annular area 111b for supporting the ring assembly 112. A wafer is an example of the substrate W. The annular area 111b of the body 111 surrounds the central area 111a of the body 111 as viewed in plan. The substrate W is placed on the central area 111a of the body 111. The ring assembly 112 is placed on the annular area 111b of the body 111 to surround the substrate W on the central area 111a of the body 111. Thus, the central area 111a is also referred to as a substrate support surface for supporting the substrate W. The annular area 111b is also referred to as a ring support surface for supporting the ring assembly 112.

In one or more embodiments of the present disclosure, the body 111 includes a base 1110 and an electrostatic chuck (ESC) 1111. The base 1110 includes a conductive member. The conductive member in the base 1110 may serve as a lower electrode. The ESC 1111 is located on the base 1110. The ESC 1111 includes a ceramic member 1111a and an electrostatic electrode 1111b inside the ceramic member 1111a. The ceramic member 1111a includes the central area 111a. In one or more embodiments of the present disclosure, the ceramic member 1111a also includes the annular area 111b. Another member surrounding the ESC 1111, such as an annular ESC or an annular insulating member, may include the annular area 111b. In this case, the ring assembly 112 may be located on either the annular ESC or the annular insulating member, or may be located on both the ESC 1111 and the annular insulating member. At least one RF/DC electrode coupled to an RF power supply 31, a DC power supply 32, or both (described later) may be located inside the ceramic member 1111a. In this case, at least one RF/DC electrode serves as a lower electrode. When a bias RF signal, a DC signal, or both (described later) are provided to at least one RF/DC electrode, the RF/DC electrode is also referred to as a bias electrode. The conductive member in the base 1110 and at least one RF/DC electrode may serve as multiple lower electrodes. The electrostatic electrode 1111b may also serve as a lower electrode. Thus, the substrate support 11 includes at least one lower electrode.

The ring assembly 112 includes one or more annular members. In one or more embodiments of the present disclosure, one or more annular members include one or more edge rings and at least one cover ring. The edge ring is formed from a conductive material or an insulating material. The cover ring is formed from an insulating material.

The substrate support 11 may also include a temperature control module that adjusts the temperature of at least one of the ESC 1111, the ring assembly 112, or the substrate to be a target temperature. The temperature control module may include a heater, a heat-transfer medium, a channel 1110a, or a combination of these. The channel 1110a allows a heat-transfer fluid such as brine or gas to flow. In one or more embodiments of the present disclosure, the channel 1110a is defined in the base 1110, and one or more heaters are located in the ceramic member 1111a in the ESC 1111. The substrate support 11 may include a heat-transfer gas supply to supply a heat-transfer gas into a space between the back surface of the substrate W and the central area 111a.

The shower head 13 introduces at least one process gas from the gas supply 20 into the plasma processing space 10s. The shower head 13 has at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The shower head 13 also includes at least one upper electrode. In addition to the shower head 13, the gas guide unit may include one or more side gas injectors (SGIs) installed in one or more openings in the side wall 10a.

The gas supply 20 may include at least one gas source 21 and at least one flow controller 22. In one or more embodiments of the present disclosure, the gas supply 20 supplies at least one process gas from the corresponding gas source 21 to the shower head 13 through the corresponding flow controller 22. The flow controller 22 may include, for example, a mass flow controller or a pressure-based flow controller. The gas supply 20 may further include at least one flow rate modulator that allows supply of at least one process gas at a modulated flow rate or in a pulsed manner.

The power supply 30 includes the RF power supply 31 that is coupled to the plasma processing chamber 10 through at least one impedance matching circuit. The RF power supply 31 provides at least one RF signal (RF power) to at least one lower electrode, to at least one upper electrode, or to both the electrodes. This causes plasma to be generated from at least one process gas supplied into the plasma processing space 10s. The RF power supply 31 may thus at least partially serve as the plasma generator 12. A bias RF signal is provided to at least one lower electrode to generate a bias potential in the substrate W, thus drawing ion components in the plasma to the substrate W.

In one or more embodiments of the present disclosure, the RF power supply 31 includes a first RF generator 31a and a second RF generator 31b. The first RF generator 31a is coupled to at least one lower electrode, to at least one upper electrode, or to both the electrodes through at least one impedance matching circuit and generates a source RF signal (source RF power) for plasma generation. In one or more embodiments of the present disclosure, the source RF signal has a frequency in a range of 10 to 150 MHz. In one or more embodiments of the present disclosure, the first RF generator 31a may generate multiple source RF signals with different frequencies. The generated one or more source RF signals are provided to at least one lower electrode, to at least one upper electrode, or to both the electrodes.

The second RF generator 31b is coupled to at least one lower electrode through at least one impedance matching circuit and generates a bias RF signal (bias RF power). The bias RF signal may have a frequency that is the same as or different from the frequency of the source RF signal. In one or more embodiments of the present disclosure, the bias RF signal has a lower frequency than the source RF signal. In one or more embodiments of the present disclosure, the bias RF signal has a frequency in a range of 100 kHz to 60 MHz. In one or more embodiments of the present disclosure, the second RF generator 31b may generate multiple bias RF signals with different frequencies. The generated one or more bias RF signals are provided to at least one lower electrode. In one or more embodiments of the present disclosure, at least one of the source RF signal or the bias RF signal may be pulsed.

The power supply 30 may also include the DC power supply 32 coupled to the plasma processing chamber 10. The DC power supply 32 includes a first DC generator 32a and a second DC generator 32b. In one or more embodiments of the present disclosure, the first DC generator 32a is coupled to at least one lower electrode and generates a first DC signal. The generated first DC signal is applied to at least one lower electrode. In one or more embodiments of the present disclosure, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses is applied to at least one lower electrode, to at least one upper electrode, or to both the electrodes. The voltage pulses may have a rectangular, trapezoidal, or triangular pulse waveform, or a combination of these pulse waveforms. In one or more embodiments of the present disclosure, a waveform generator for generating a sequence of voltage pulses based on DC signals is coupled between the first DC generator 32a and at least one lower electrode. Thus, the first DC generator 32a and the waveform generator are included in a voltage pulse generator. When the second DC generator 32b and the waveform generator are included in a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31, or the first DC generator 32a may replace the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

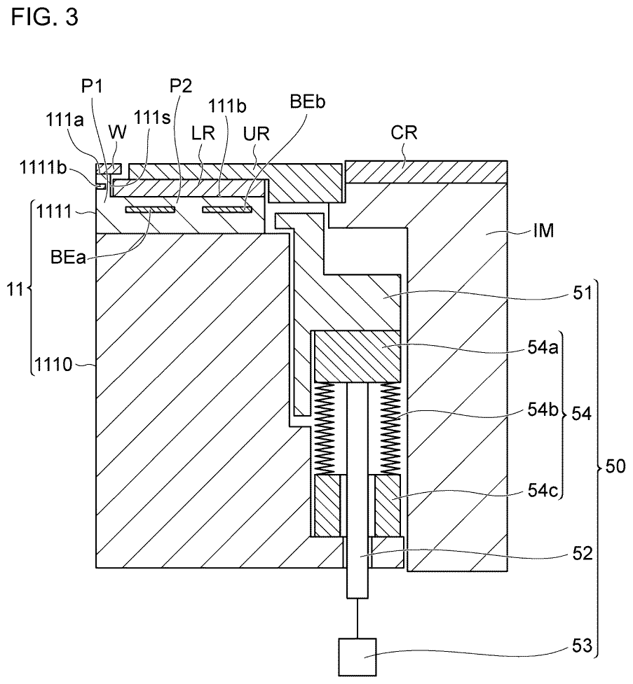

FIG. 3 will now be referred to. FIG. 3 is a diagram of a substrate support and a lifter in one exemplary embodiment. The substrate support 11 and the lifter 50 shown in FIG. 3 may be included in the plasma processing apparatus 1.

As described above, the substrate support 11 supports an edge ring UR (upper edge ring). The edge ring UR is a part of the ring assembly 112. The edge ring UR surrounds the substrate W on the substrate support 11. The edge ring UR is formed from a conductive material such as silicon, silicon carbide, or tungsten.

As described above, the substrate support 11 includes the base 1110 and the ESC 1111. The base 1110 is a conductive member or includes a conductive member inside. The base 1110 (or its conductive member) is electrically coupled to an RF power supply, to at least one bias power supply, or to both the power supplies. The RF power supply is a first RF generator 31a and forms the plasma generator 12. The at least one bias power supply includes a second RF generator 31b, a first DC generator 32a, or both the generators. The at least one bias power supply generates an electrical bias to draw ions from plasma into the substrate W on the substrate support 11. The electrical bias includes a sequence of the above bias RF signals, the above voltage pulses, or both the bias RF signals and the voltage pulses.

The ESC 1111 is located on the base 1110. The ESC 1111 includes a first portion P1 and a second portion P2. The first portion P1 includes the substrate support surface (or the central area 111a) as its upper surface. Each of the first portion P1 and the substrate support surface is a substantially circular flat surface. Each of the first portion P1 and the substrate support surface has a central axis aligned with the central axis of the substrate support 11. The first portion P1 includes the electrostatic electrode 1111b described above. When the electrostatic electrode 1111b receives a DC voltage applied from a DC power supply, an electrostatic attraction is generated between the first portion P1 and the substrate W. The first portion P1 holds the substrate W under the generated electrostatic attraction.

The second portion P2 extends circumferentially about the central axis of the substrate support 11 to surround the first portion P1. The second portion P2 includes the ring support surface (or the annular area 111b) as its upper surface. Each of the second portion P2 and the ring support surface is a substantially annular flat surface. The second portion P2 may include at least one electrostatic electrode. The second portion P2 may include an electrode BEa and an electrode BEb as at least one electrostatic electrode. The electrode BEa and the electrode BEb form a bipolar electrode. The electrode BEa and the electrode BEb receive a voltage applied from at least one power supply to have a potential difference between them. This generates an electrostatic attraction between the edge ring UR and the second portion P2. The second portion P2 holds the edge ring UR under the generated electrostatic attraction.

In one or more embodiments of the present disclosure, the ring support surface extends at a lower level than the substrate support surface. In this case, the first portion P1 includes a sidewall surface 111s extending between the substrate support surface and the ring support surface. In this case, an edge ring LR (lower edge ring) may be located on the ring support surface along the sidewall surface 111s. The edge ring LR is a part of the ring assembly 112. The edge ring LR may be formed from a conductive material such as silicon, silicon carbide, or tungsten. The edge ring LR may be formed from an insulating material such as quartz. In this case, the edge ring UR is located on the edge ring LR. The ring support surface and the sidewall surface 111s are protected by the edge ring LR.

As shown in FIG. 3, the substrate support 11 may further include a cover ring CR and an insulating member IM. The insulating member IM is formed from an insulating material such as quartz, and is substantially cylindrical. The insulating member IM extends circumferentially about the central axis of the substrate support 11 to surround the base 1110 and the ESC 1111. The cover ring CR is a substantially circular disk and is located on the insulating member IM to surround the edge ring UR.

The plasma processing apparatus 1 further includes a lifter 50. The lifter 50 includes a conductive ring 51, at least one rod 52, an actuator 53, and at least one connector 54.

The conductive ring 51 is formed from a metal such as aluminum or a conductive material, and is substantially a ring. The conductive ring 51 extends circumferentially about the central axis of the substrate support 11 to surround the base 1110 and the ESC 1111 inward from the insulating member IM. The conductive ring 51 is electrically coupled to (e.g., electrically conductive with) the edge ring UR while supporting the edge ring UR placed on the conductive ring 51. The areas exposed on the surface of the conductive ring 51 may be covered with a film that is resistant to plasma. The film may be formed from a material such as an aluminum oxide or yttrium fluoride, and may be formed by anodic oxidation or spraying.

The at least one rod 52 extends in the vertical direction below the conductive ring 51. The at least one rod 52 may be insulating. This structure can reduce the likelihood that the electrical bias flows into the actuator 53 through the at least one rod 52. In one or more embodiments of the present disclosure, the lifter 50 may include multiple rods 52 as the at least one rod 52. The rods 52 are arranged circumferentially about the central axis of the substrate support 11. The rods 52 may be circumferentially arranged at equal intervals.

The actuator 53 is located below the at least one rod 52 and is connected to the at least one rod 52. The actuator 53 raises and lowers the edge ring with the at least one rod 52 and the conductive ring 51. The actuator 53 may be, for example, a pneumatic cylinder, a hydraulic cylinder, or a motor.

The at least one connector 54 electrically couples the conductive ring 51 and the base 1110 (or its conductive member). The at least one connector 54 maintains the electrical coupling following the movement of the conductive ring 51. The at least one connector 54 may be deformable in response to the movement of the conductive ring 51. The lifter 50 including multiple rods 52 may include multiple connectors 54 as the at least one connector 54.

In the example shown in FIG. 3, the at least one connector 54 includes an upper portion 54a, a deformable portion 54b, and a lower portion 54c. The upper portion 54a, the deformable portion 54b, and the lower portion 54c are each formed from a conductive material. The upper portion 54a is located immediately below the conductive ring 51 and is fixed to the conductive ring 51. The upper portion 54a is electrically conductive with the conductive ring 51. The lower portion 54c is located below the upper portion 54a and is fixed to the base 1110. The lower portion 54c is electrically conductive with the base 1110.

The deformable portion 54b extends between the upper portion 54a and the lower portion 54c. The deformable portion 54b has an upper end fixed to the upper portion 54a and a lower end fixed to the lower portion 54c. The deformable portion 54b is electrically conductive with the upper portion 54a and the lower portion 54c. The deformable portion 54b may be a bellows as shown in FIG. 3.

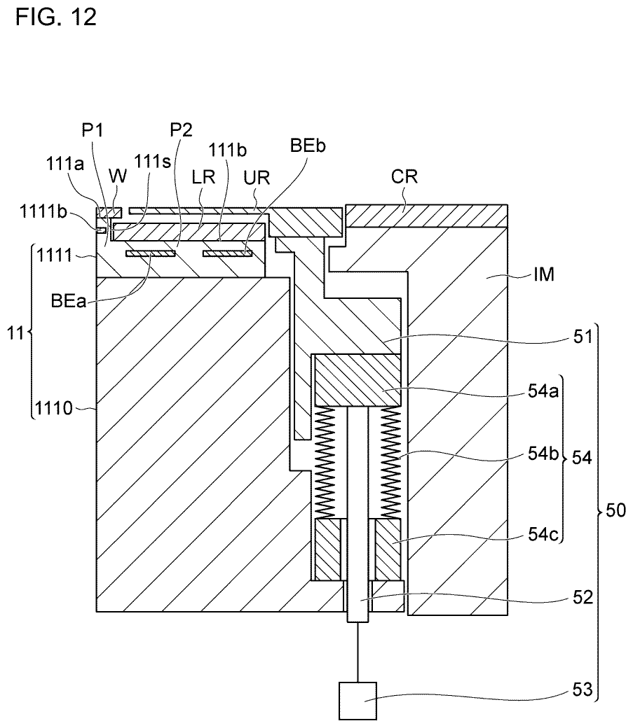

The at least one rod 52 extends through the lower portion 54c, the deformable portion 54b, and to an area immediately below the upper portion 54a. When the at least one rod 52 is moved upward by the actuator 53, the edge ring UR is raised upward with the upper portion 54a and the conductive ring 51. The edge ring UR is raised by a decrease in its thickness to reduce the difference between the upper end position of a plasma sheath above the substrate W and the upper end position of a plasma sheath above the edge ring UR (refer to FIG. 12). In the plasma processing apparatus 1, the connector 54 maintains a first state (e.g., a conductive state) in which the base 1110 and the edge ring UR are electrically coupled to each other although the edge ring UR is raised upward from the ESC 1111. In the plasma processing apparatus 1, the edge ring UR does not enter an electrically floating state. Thus, the edge ring UR can reduce the difference between the upper end position of the plasma sheath above the substrate W and the upper end position of the plasma sheath above the edge ring UR.

The connector 54 may be a cylindrical member with multiple slits on the sidewall surface to be elastically deformable in its longitudinal direction. For example, the connector 54 may be a spring (flexible member).

As described above, the lifter 50 electrically couples (e.g., allows electrical conduction between) the conductive ring 51 and the edge ring UR while supporting the edge ring UR on the conductive ring 51. More specifically, the lifter 50 can establish (e.g., change to, where “establish” throughout the specification can be interpreted as “changed to” or “operate in”) the first state (e.g., the conductive state) in which the edge ring UR and the base 1110 are electrically coupled to each other. In the state shown in FIG. 3, the conductive ring 51 is lowered and spaced from the edge ring UR. When the conductive ring 51 is in contact with the edge ring UR placed on the conductive ring 51, the first state (e.g., the conductive state) is established in which the edge ring UR and the base 1110 are electrically coupled to each other.

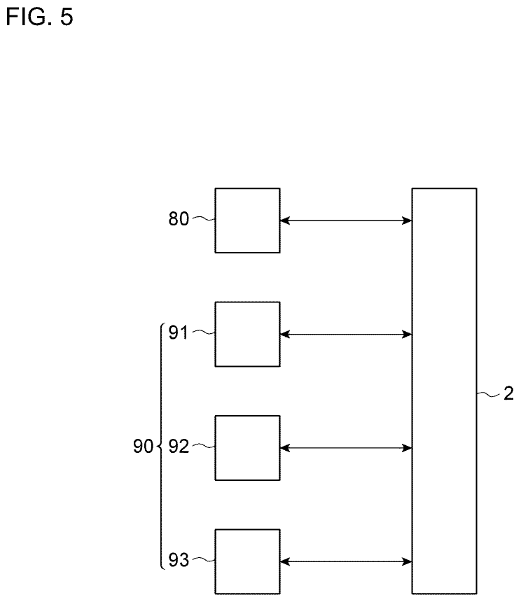

The plasma processing apparatus 1 further includes a switch 80 (refer to FIG. 5). The switch 80 can switch between establishing the first state in which the edge ring UR and the base 1110 are electrically coupled to each other (e.g., the conductive state) and establishing a second state in which the edge ring UR and the base 1110 are electrically disconnected from each other (e.g., a nonconductive state). The controller 2 may control the switch 80 to switch between establishing the first state and establishing the second state.

In FIG. 3, the switch 80 is the lifter 50. More specifically, the lifter 50 can lower the conductive ring 51 with the rod 52 using the actuator 53 to separate the conductive ring 51 from the edge ring UR. In other words, the lifter 50 can disconnect the conductive ring 51 from the edge ring UR to establish the second state.

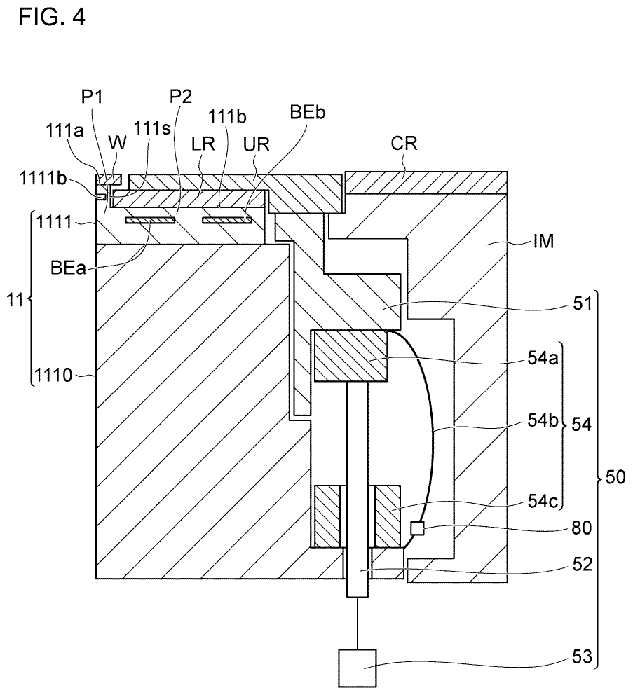

FIG. 4 will now be referred to. FIG. 4 is a diagram of a substrate support and a lifter in another exemplary embodiment. The substrate support 11 and the lifter 50 shown in FIG. 4 may be included in the plasma processing apparatus 1. The embodiment in FIG. 4 will now be described focusing on its differences from the embodiment in FIG. 3.

As shown in FIG. 4, the lifter 50 may include the deformable portion 54b that is a contact band in place of the bellows. The deformable portion 54b may have an upper end fixed to the conductive ring 51. The deformable portion 54b may have a lower end fixed to the base 1110. The deformable portion 54b shown in FIG. 4 is flexible in the vertical direction. As shown in FIG. 4, the deformable portion 54b may have a substantially arc shape protruding outward. In this case, the insulating member IM may have a recess to receive a part of the deformable portion 54b.

The plasma processing apparatus 1 including the lifter 50 shown in FIG. 4 further includes the switch 80. The switch 80 may be a part of the lifter 50. The switch 80 includes a switching element and is connected between the connector 54 and the conductive ring 51 or between the connector 54 and the base 1110. The switching element in the switch 80 being ON (closed) establishes the first state described above. The switching element in the switch 80 being OFF (open) establishes the second state described above. The controller 2 may control the switch 80 (or the switching element) to switch between establishing the first state and establishing the second state.

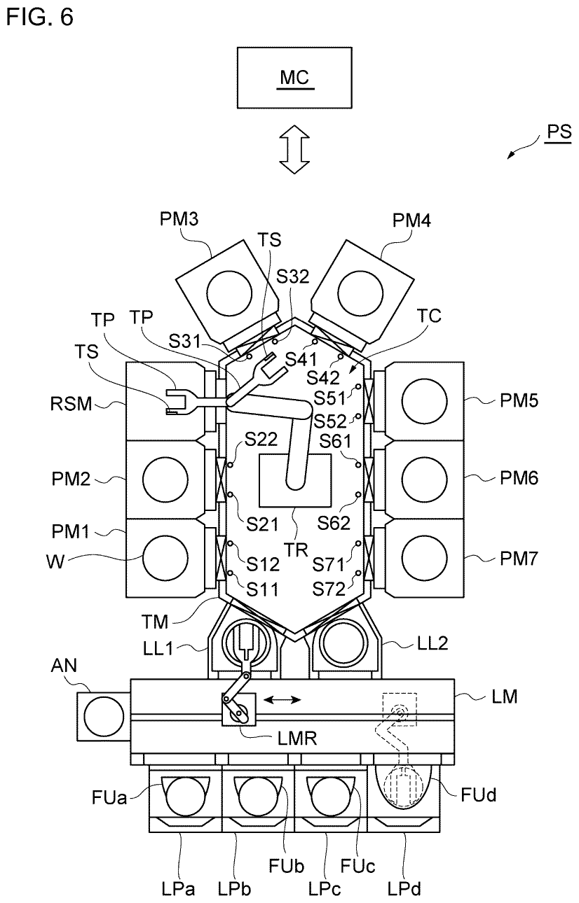

FIG. 6 will now be referred to. FIG. 6 is a diagram of a substrate processing system according to one exemplary embodiment. A substrate processing system PS shown in FIG. 6 includes a transfer module TM, multiple process modules PM1 to PM7 (multiple substrate processing modules), and a controller MC. The substrate processing system PS may further include tables LPa to LPd, containers FUa to FUd, a loader module LM, an aligner AN, a loadlock module LL1, a loadlock module LL2, and a stocker module RSM (ring stocker). The substrate processing system PS may include one or more tables, containers, and loadlock modules. The substrate processing system PS may include two or more process modules.

The tables LPa to LPd are arranged along one edge of the loader module LM. The containers FUa to FUd are mounted on the respective tables LPa to LPd. The containers FUa to FUd are each, for example, a container called a front-opening unified pod (FOUP). The containers FUa to FUd each store substrates W.

The loader module LM includes a transfer chamber. The transfer chamber in the loader module LM has an atmospheric pressure. The loader module LM includes a transfer robot LMR. The controller MC controls the transfer robot LMR. The transfer robot LMR transfers a substrate W through the transfer chamber in the loader module LM. The transfer robot LMR may transfer the substrate W between the containers FUa to FUd and the aligner AN, between the aligner AN and the loadlock modules LL1 and LL2, and between the loadlock modules LL1 and LL2 and the containers FUa to FUd. The aligner AN is connected to the loader module LM. The aligner AN adjusts (aligns) the position of the substrate W.

The loadlock module LL1 and the loadlock module LL2 are connected between the transfer chamber in the loader module LM and a transfer chamber TC in the transfer module TM. The loadlock module LL1 and the loadlock module LL2 each serve as a preliminary decompression chamber. A gate valve is located between the preliminary decompression chamber in each of the loadlock module LL1 and the loadlock module LL2 and the transfer chamber in the loader module LM. A gate valve is located between the preliminary decompression chamber in each of the loadlock module LL1 and the loadlock module LL2 and the transfer chamber TC in the transfer module TM.

The transfer module TM includes the transfer chamber TC (vacuum atmosphere transfer chamber) and a transfer robot TR. The transfer chamber TC has an internal space that can be decompressed. The transfer robot TR includes picks TP (end-effectors). The transfer robot TR may include at least two picks TP. In the illustrated example, the transfer robot TR includes two picks TP. One pick TP is located above the other pick TP. The transfer robot TR transfers a substrate W on one of the two picks TP through the transfer chamber TC. The controller MC controls the transfer robot TR.

The transfer module TM may include position detection sensors S11 and S12. The position detection sensors S11 and S12 are installed on the transfer path for the substrate W and the edge ring from the transfer module TM to the process module PM1. The position detection sensors S11 and S12 are used to correct the positions of the substrate W and the edge ring that are transferred from the transfer module TM to the process module PM1. The position detection sensors S11 and S12 are located, for example, adjacent to the gate valve that separates the transfer module TM and the process module PM1. The position detection sensors S11 and S12 are located, for example, at a distance from each other being smaller than the outer diameter of the substrate W and smaller than the inner diameter of the edge ring. The transfer module TM may include position detection sensors S21, S22, S31, S32, S41, S42, S51, S52, S61, S62, S71, and S72, similarly to the position detection sensors S11 and S12. The position detection sensors S21 and S22 are installed on the transfer path for the substrate W and the edge ring from the transfer module TM to the process module PM2. The position detection sensors S31 and S32 are installed on the transfer path for the substrate W and the edge ring from the transfer module TM to the process module PM3. The position detection sensors S41 and S42 are installed on the transfer path for the substrate W and the edge ring from the transfer module TM to the process module PM4. The position detection sensors S51 and S52 are installed on the transfer path for the substrate W and the edge ring from the transfer module TM to the process module PM5. The position detection sensors S61 and S62 are installed on the transfer path for the substrate W and the edge ring from the transfer module TM to the process module PM6. The position detection sensors S71 and S72 are installed on the transfer path for the substrate W and the edge ring from the transfer module TM to the process module PM7.

In one or more embodiments of the present disclosure, the transfer robot TR transfers an edge ring for a substrate support in one of the process modules PM1 to PM7. The edge ring is the edge ring UR or a set of rings including the edge ring UR and the edge ring LR. The edge ring is placed on either of the two picks TP and is transferred. Each pick TP includes a sensor TS. The sensor TS is an optical sensor that measures the position of a ring member, such as the edge ring, on the substrate support.

Each of the process modules PM1 to PM7 performs dedicated substrate processing and includes a processing chamber (substrate processing chamber). A gate valve is located between each processing chamber and the transfer chamber TC. At least one of the process modules PM1 to PM7 is the plasma processing apparatus 1.

The stocker module RSM (ring stocker) is connected to the transfer chamber TC with a gate valve. The stocker module RSM includes a chamber that can store multiple edge rings.

The controller MC controls the components of the substrate processing system PS. The controller MC may be a computer including a processor, a storage, an input device, and a display. The controller MC executes a control program stored in the storage to control the components of the substrate processing system PS based on recipe data stored in the storage.

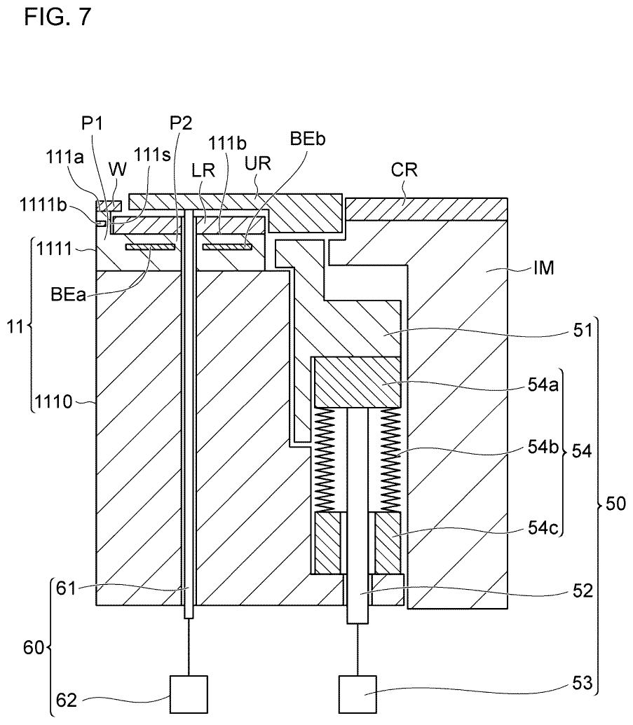

FIG. 7 will now be referred to. FIG. 7 is a diagram of a substrate support and a lifter in still another exemplary embodiment. The substrate support 11 and the lifter 50 shown in FIG. 7 may be included in the plasma processing apparatus 1. The plasma processing apparatus 1 including the substrate support 11 and the lifter 50 shown in FIG. 7 may be included in the substrate processing system PS as a process module. The embodiment in FIG. 7 will now be described focusing on its differences from the embodiment in FIG. 3.

In the embodiment in FIG. 7, the substrate support 11 has multiple through-holes extending through the substrate support 11 in the vertical direction. The through-holes in the substrate support 11 are arranged circumferentially about the central axis of the substrate support 11. The through-holes in the substrate support 11 may be arranged at equal intervals. The edge ring LR has multiple through-holes aligned with the respective through-holes in the substrate support 11.

In the embodiment in FIG. 7, a lifter 60 can raise the edge ring UR upward from the substrate support 11. The lifter 60 includes multiple lift pins 61 and an actuator 62. The lift pins 61 are placed through the respective through-holes in the substrate support 11. The actuator 62 is connected to the lift pins 61 to move the lift pins 61 vertically.

With the upper ends of the lift pins 61 in contact with the edge ring UR, the actuator 62 moves the lift pins 61 upward to raise the edge ring UR upward from the substrate support 11. In this state, the transfer robot TR moves the corresponding pick TP to a position below the edge ring UR. The lift pins 61 then move downward to transfer the edge ring UR to the pick TP. The edge ring UR is then transferred into the stocker module RSM by the transfer robot TR.

An edge ring UR for replacement is then transferred from the stocker module RSM into the chamber 10 by the transfer robot TR. The lift pins 61 are moved upward by the actuator 62 to transfer the edge ring UR to the lift pins 61. The pick TP then moves out of the chamber 10, and the lift pins 61 are moved downward. This places the edge ring UR for replacement onto the substrate support 11.

The plasma processing apparatus 1 including the lifter 50 shown in FIG. 7 includes the lifter 60 as the switch 80. All lift pins 61 in the lifter 60 are formed from an insulating material. When the lifter 60 positions all lift pins 60 to have the edge ring UR supported on the conductive ring 51 and electrically coupled to the conductive ring 51, the first state described above is established. When the lifter 60 raises the edge ring UR upward from the conductive ring 51 and separates the edge ring UR from the conductive ring 51, the second state described above is established.

The plasma processing apparatus 1 may include, in place of or in addition to the lifter 60, another lifter. The other lifter may raise the set of rings including both the edge ring UR and the edge ring LR upward from the substrate support 11, the conductive ring 51, or both.

The switch 80 described above can switch between establishing the first state and the second state as appropriate. In the second state, the electrical bias, the source RF signal, or both are not provided to the edge ring UR through the base 1110 or the conductive ring 51. With the switch 80, the plasma processing is performed in the chamber 10 in the second state, reducing wear of the edge ring UR caused by the chemical species in the plasma.

FIG. 5 will now be referred to. FIG. 5 is a diagram of the switch and a sensor in the plasma processing apparatus according to one exemplary embodiment. As shown in FIG. 5, the plasma processing apparatus 1 according to various exemplary embodiments may further include at least one sensor 90. The at least one sensor 90 measures the amount of a deposit on the edge ring UR.

The sensor 90 may include at least one selected from the group consisting of sensors 91, 92, and 93. The sensor 91 is an emission spectrometer that analyzes the emission of plasma in the chamber 10. The sensor 91 measures different light intensities at a predetermined wavelength when a deposit is on the edge ring UR and when the deposit is removed from the edge ring UR. The sensor 91 can thus estimate the amount of the deposit on the edge ring UR based on the measured light intensities.

The sensor 92 is an optical sensor including a light source such as a laser, and detects the thickness of the deposit on the edge ring UR. The sensor 92 is installed on, for example, the ceiling of the chamber 10. The sensor 92 can estimate the amount of the deposit on the edge ring UR based on the measured thickness of the deposit.

The sensor 93 is an impedance measurement device and is connected to the base 1110. The impedance of the base 1110 measured with the sensor 93 varies depending on the amount of the deposit on the edge ring UR. The sensor 93 can estimate the amount of the deposit on the edge ring UR based on the measured impedance.

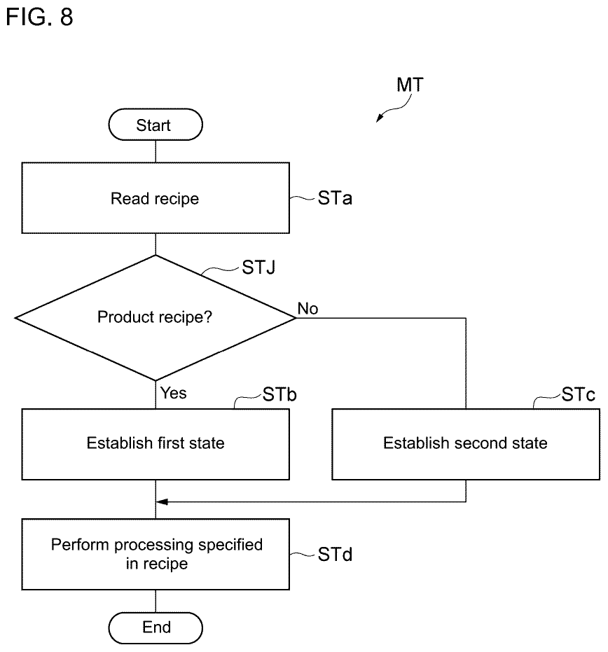

Plasma processing methods according to various exemplary embodiments will now be described with reference to FIGS. 8 to 10. FIGS. 8 to 10 are flowcharts of the plasma processing methods according to the exemplary embodiments. The plasma processing methods shown in FIGS. 8 to 10 may be implemented using the plasma processing apparatus 1. To implement the plasma processing methods, the controller 2 may control the components of the plasma processing apparatus 1.

FIG. 8 will now be referred to. A plasma processing method shown in FIG. 8 (hereafter referred to as the method MT) starts in step STa. In step STa, the controller 2 reads a recipe (e.g., predetermined plasma processing process).

In subsequent step STJ, the controller 2 determines whether the read recipe is a product recipe. The product recipe is a recipe for performing plasma processing on the substrate W on the substrate support 11. When the read recipe is determined to be a product recipe in step STJ, the controller 2 controls the switch 80 to establish the first state described above in step STb. When the read recipe is determined not to be a product recipe in step STJ, the controller 2 controls the switch 80 to establish the second state described above in step STc.

In subsequent step STd, the controller 2 performs the plasma processing specified in the read recipe. When the read recipe is a product recipe, the controller 2 controls the components of the plasma processing apparatus 1 to perform the plasma processing, for example, plasma etching, on the substrate W on the substrate support 11 in step STd while maintaining the first state described above. When the read recipe is not a product recipe, the controller 2 controls the components of the plasma processing apparatus 1 to perform plasma cleaning of the chamber 10 in step STd while maintaining the second state described above.

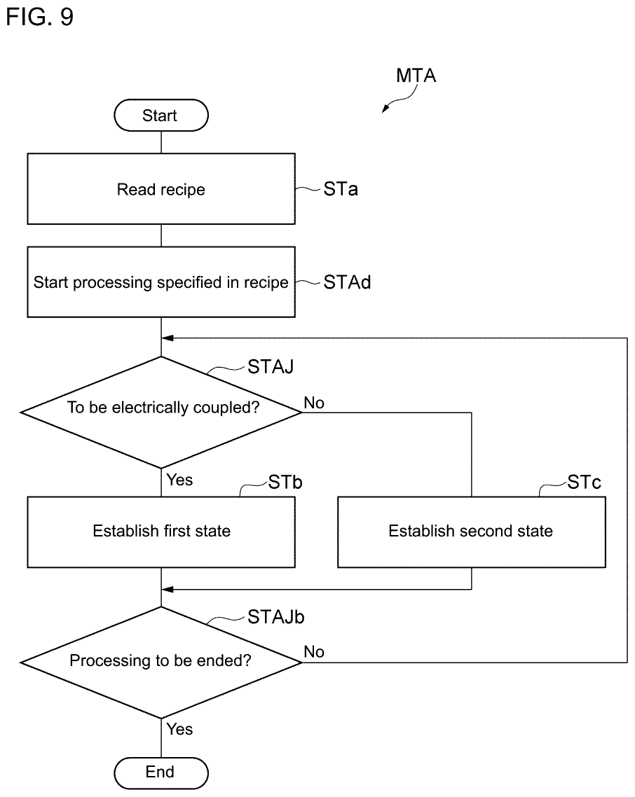

FIG. 9 will now be referred to. A plasma processing method shown in FIG. 9 (hereafter referred to as the method MTA) starts in step STa, as with the method MT. In subsequent step STAd, the controller 2 controls the components of the plasma processing apparatus 1 to start the plasma processing specified in the read recipe. The plasma processing may be plasma cleaning of the chamber 10. In one example, the plasma processing is plasma cleaning to remove a carbon-containing deposit on the edge ring UR. A gas used in the plasma processing includes a gas that can remove the deposit, for example, an oxygen-containing gas. At the start of the plasma processing, the controller 2 may control the switch 80 to establish the first state described above.

In subsequent step STAJ, the controller 2 determines whether the edge ring UR and the base 1110 are to be electrically coupled. More specifically, when the amount of the deposit on the edge ring UR measured by the at least one sensor 90 is greater than a threshold, the controller 2 determines that the edge ring UR and the base 1110 are to be electrically coupled in step STAJ. When the amount of the deposit on the edge ring UR measured by the at least one sensor 90 is less than or equal to the threshold, the controller 2 determines that the edge ring UR and the base 1110 are not to be electrically coupled in step STAJ.

When the light intensity of the plasma is less than or equal to a threshold at the predetermined wavelength measured by the sensor 91 (e.g., emission wavelength based on carbon), the amount of the deposit on the edge ring UR may be determined to be less than or equal to the threshold in step STAJ. In some embodiments, when the thickness of the deposit on the edge ring UR measured by the sensor 92 is less than or equal to a threshold, the amount of the deposit on the edge ring UR may be determined to be less than or equal to the threshold in step STAJ. In some embodiments, when the impedance measured by the sensor 93 is less than or equal to a threshold, the amount of the deposit on the edge ring UR may be determined to be less than or equal to the threshold in step STAJ.

When the edge ring UR and the base 1110 are determined to be electrically coupled in step STAJ, the controller 2 controls the switch 80 to establish the first state described above in step STb. When the edge ring UR and the base 1110 are determined not to be electrically coupled in step STAJ, the controller 2 controls the switch 80 to establish the second state described above in step STc.

In subsequent step STAJb, the controller 2 determines whether to end the processing. When the processing is determined not to be ended in step STAJb, the plasma processing started in step STAd continues, and the processing in step STAJ and the subsequent steps is repeated. When the processing is determined to be ended in step STAJb, the controller 2 ends the method MTA.

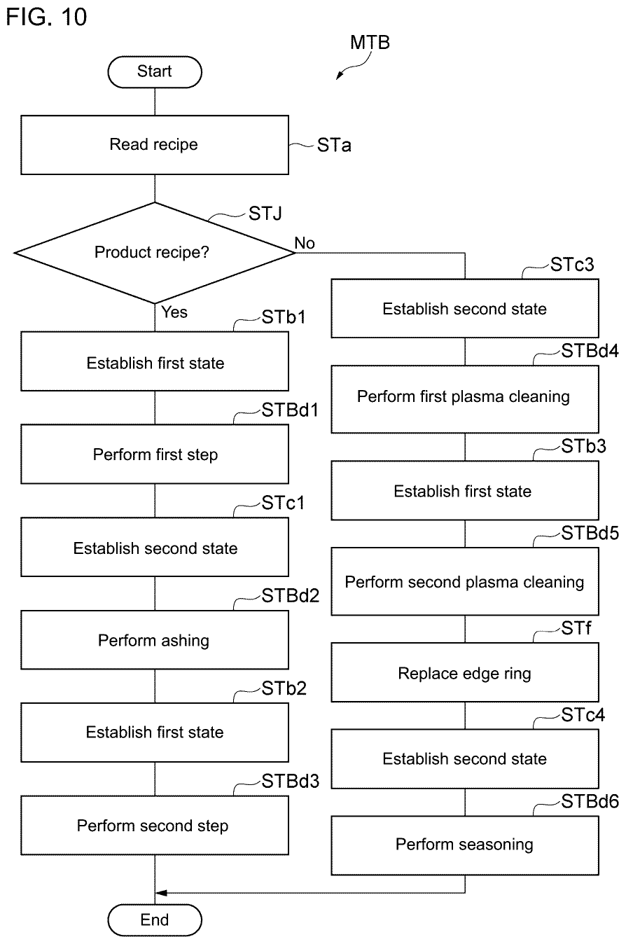

FIG. 10 will now be referred to. A plasma processing method shown in FIG. 10 (hereafter referred to as the method MTB) starts in step STa, as with the method MT. The method MTB includes determination in step STJ, as with the method MT. The edge ring UR is placed on the substrate support 11 and the conductive ring 51 at the start of the method MTB or immediately after step STJ.

When the read recipe is determined to be a product recipe in step STJ, the controller 2 controls the switch 80 to establish the first state described above in step STb1.

In subsequent step STBd1, the controller 2 controls the components of the plasma processing apparatus 1 to perform a first step specified in the read recipe. The first step includes, as the plasma processing specified in the recipe, plasma etching to form a recess on the substrate W on the substrate support 11. A gas used for the plasma etching may contain a fluorocarbon, a hydrofluorocarbon, or both.

In subsequent step STc1, the controller 2 controls the switch 80 to establish the second state described above.

In subsequent step STBd2, the controller 2 controls the components of the plasma processing apparatus 1 to perform ashing specified in the read recipe. In the ashing, the deposit on the substrate W on the substrate support 11 is removed with a chemical species in the plasma generated from an ashing gas. The ashing gas may contain an oxygen-containing gas.

In subsequent step STb2, the controller 2 controls the switch 80 to establish the first state described above.

In subsequent step STBd3, the controller 2 controls the components of the plasma processing apparatus 1 to perform a second step specified in the read recipe. The second step includes, as the plasma processing specified in the recipe, plasma etching to increase the depth of the recess on the substrate W on the substrate support 11. A gas used in the plasma etching may contain a fluorocarbon, a hydrofluorocarbon, or both, similarly to the gas used in the first step.

When the read recipe is determined not to be a product recipe in step STJ described above, the controller 2 controls the switch 80 to establish the second state described above in step STc3.

In subsequent step STBd4, the controller 2 controls the components of the plasma processing apparatus 1 to perform the plasma processing specified in the read recipe, or specifically, first plasma cleaning of the chamber 10. A gas used in step STBd4 may contain an oxygen-containing gas.

In subsequent step STb3, the controller 2 controls the switch 80 to establish the first state described above.

In subsequent step STBd5, the controller 2 controls the components of the plasma processing apparatus 1 to perform the plasma processing specified in the read recipe, or specifically, second plasma cleaning of the chamber 10. A gas used in step STBd5 may contain an oxygen-containing gas.

In subsequent step STf, the edge ring on the substrate support 11 is replaced with an edge ring transferred from the stocker module RSM using the transfer robot TR.

In subsequent step STc4, the controller 2 controls the switch 80 to establish the second state described above.

In subsequent step STBd6, the controller 2 controls the components of the plasma processing apparatus 1 to perform the plasma processing specified in the read recipe, or specifically, seasoning of the chamber 10 (i.e., conditioning the chamber walls to achieve stable and repeatable process results, seasoning as is known). In step STBd6, plasma is generated from a seasoning gas in the chamber 10.

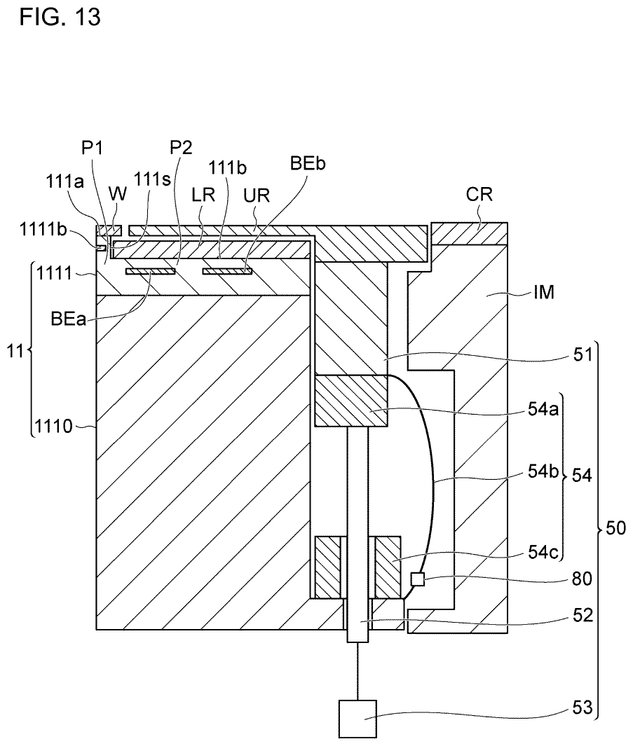

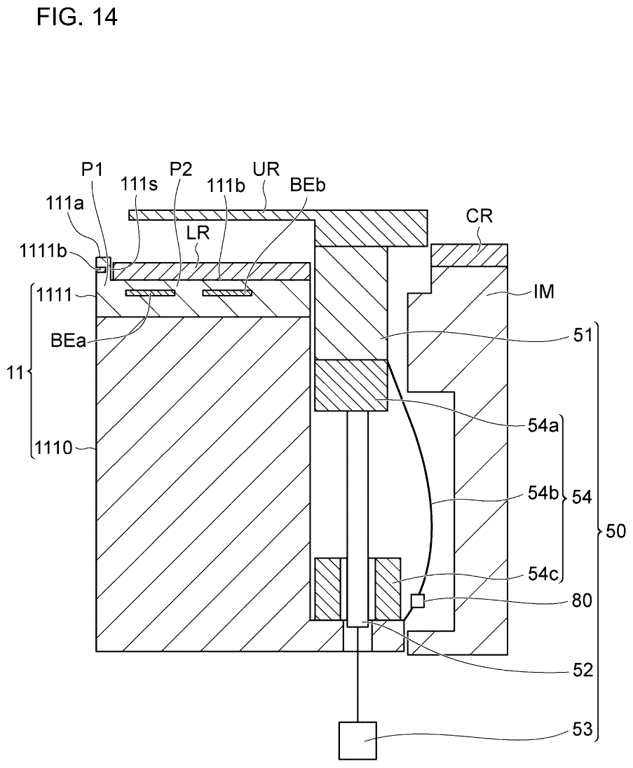

FIGS. 13 and 14 will now be referred to in addition to FIG. 8. FIGS. 13 and 14 are each a diagram of a substrate support and a lifter in still another exemplary embodiment. The substrate supports 11 and the lifters 50 each shown in FIGS. 13 and 14 may be included in the plasma processing apparatus 1. The components in the embodiments in FIGS. 13 and 14 are substantially the same as the corresponding components in the embodiment in FIG. 4. The plasma processing apparatus 1 including the substrate support 11 and the lifter 50 shown in FIG. 13 or FIG. 14 may be used with the method MT.

As described above, in response to the plasma processing specified in the recipe being plasma processing to be performed on the substrate W on the substrate support 11, the controller 2 controls the switch 80 to establish the first state described above in step STb. In this case, the controller 2 controls the components of the plasma processing apparatus 1 to perform the plasma processing on the substrate W in step STd. When the plasma processing is performed on the substrate W in step STd while the first state established in step STb is maintained and the edge ring UR is being raised upward from the edge ring LR (refer to FIG. 13), a deposit may be formed on the lower surface of the edge ring UR, on the upper surface (the ring support surface or the upper surface of the edge ring LR) facing the lower surface of the edge ring UR, or on both the surfaces. The deposit may contain a component contained in the process gas used in the plasma processing in step STd. The deposit may contain a carbon-containing substance. In some embodiments, the deposit may contain a metal-containing substance.

In response to the plasma processing specified in the recipe being plasma cleaning of the chamber 10 as described above, the controller 2 controls the switch 80 to establish the second state described above in step STb. In this case, the controller 2 controls the components of the plasma processing apparatus 1 to perform the plasma cleaning in step STd. The controller 2 also controls the lifter 50 to position the edge ring UR higher when the plasma cleaning is performed (refer to FIG. 14) than when the plasma processing is performed on the substrate W (refer to FIG. 13). This allows active species in the plasma to be fed into a space between the lower surface of the edge ring UR and the upper surface (the ring support surface or the upper surface of the edge ring LR) facing the lower surface of the edge ring UR, thus facilitating removal of the deposit described above.

For a deposit containing a carbon-containing substance, a source RF signal may be provided from the first RF generator 31a to generate plasma from a cleaning gas in the plasma cleaning in step STd. In this case, the level of the bias signal from the bias power supply, or specifically, the power level of the bias RF signal or the level of the voltage pulse (potential difference of the voltage pulse relative to a reference potential; e.g., 0 V) may be set to zero or to a low level. For a deposit containing a carbon-containing substance, an oxygen-containing gas may be supplied into the chamber 10 as a cleaning gas to generate plasma in the plasma cleaning in step STd.

For a deposit containing a metal-containing substance, a source RF signal may be provided from the first RF generator 31a to generate plasma from a cleaning gas in the plasma cleaning in step STd. In this case, the level of the bias signal from the bias power supply, or specifically, the power level of the bias RF signal or the level of the voltage pulse (potential difference of the voltage pulse relative to the reference potential; e.g., 0 V) may be set to a high level to remove the deposit by ion sputtering.

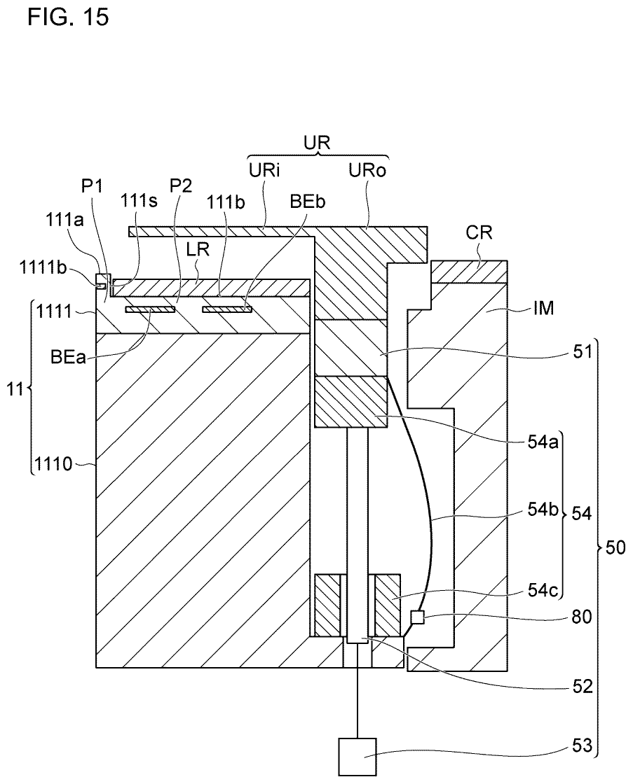

FIG. 15 will now be referred to. FIG. 15 is a diagram of a substrate support and a lifter in still another exemplary embodiment. The lifter 50 shown in FIG. 15 may be included in the plasma processing apparatus 1, in place of the lifter 50 shown in FIG. 13 or FIG. 14. With the plasma processing apparatus 1 including the lifter 50 shown in FIG. 15 as well, the method MT can be implemented as with the plasma processing apparatus 1 including the lifter 50 shown in FIG. 13 or FIG. 14. The lifter 50 shown in FIG. 15 will now be described focusing on its differences from the lifters 50 shown in FIGS. 13 and 14.

As shown in FIG. 15, the edge ring UR includes an inner circumferential portion URi and an outer circumferential portion URo. The inner circumferential portion URi extends inward from the outer circumferential portion URo and is located above the second portion P2. The outer circumferential portion URo is located on the conductive ring 51 while the conductive ring 51 is supporting the outer circumferential portion URo. The outer circumferential portion URo has a vertical length to cover the conductive ring 51 from a space above the substrate support 11 during the plasma cleaning in step STd. More specifically, the outer circumferential portion URo has a vertical length to extend between the space above the substrate support 11 and the conductive ring 51 during the plasma cleaning in step STd. This protects the conductive ring 51 from plasma generated in step STd.

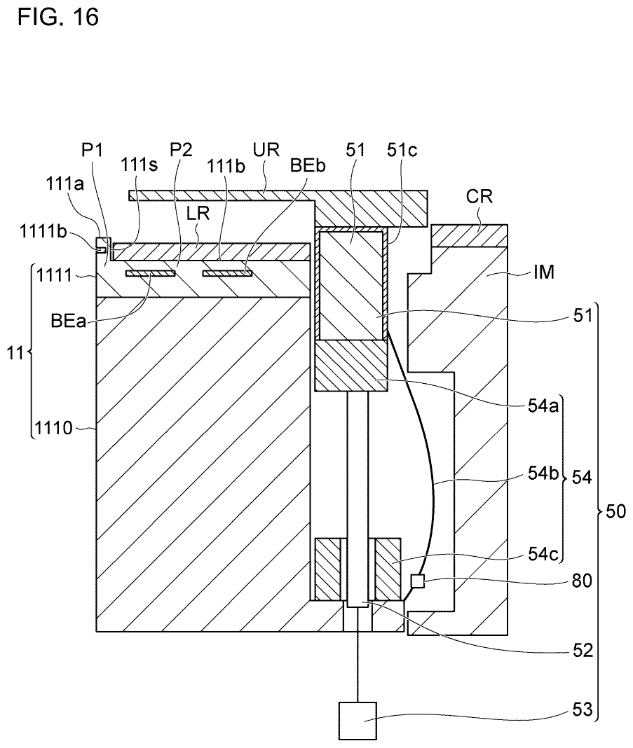

FIG. 16 will now be referred to. FIG. 16 is a diagram of a substrate support and a lifter in still another exemplary embodiment. The lifter 50 shown in FIG. 16 may be included in the plasma processing apparatus 1, in place of the lifter 50 shown in FIG. 13 or FIG. 14. With the plasma processing apparatus 1 including the lifter 50 shown in FIG. 16 as well, the method MT can be implemented as with the plasma processing apparatus 1 including the lifter 50 shown in FIG. 13 or FIG. 14. The lifter 50 shown in FIG. 16 will now be described focusing on its differences from the lifters 50 shown in FIGS. 13 and 14.

The lifter 50 shown in FIG. 16 further includes a film 51c. The film 51c covers the surface of the conductive ring 51 to protect the conductive ring 51 from plasma. The film 51c is formed from a plasma-resistant material (e.g., yttria). The film 51c between the edge ring UR and the conductive ring 51, or more specifically, the film 51c on the upper surface of the conductive ring 51, may have a capacitance of 10000 pF or greater to electrically couple (to capacitively couple) the edge ring UR and the base 1110.

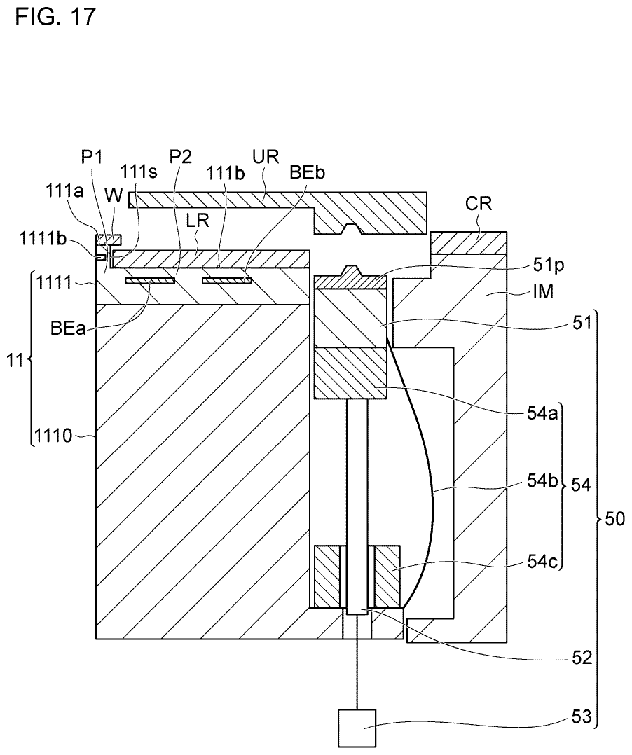

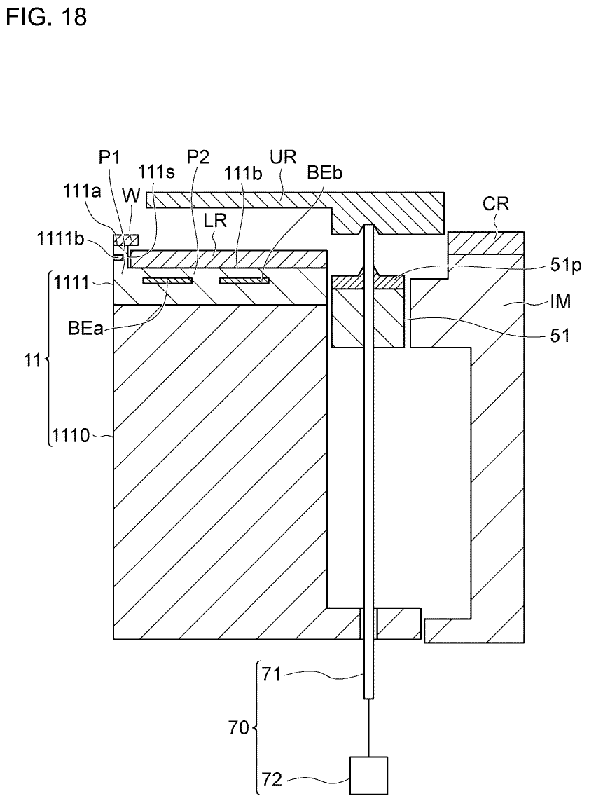

FIGS. 17 and 18 will now be referred to. FIGS. 17 and 18 are each a diagram of a substrate support and a lifter in still another exemplary embodiment. The substrate support 11 and the lifter 50 shown in FIG. 17 or FIG. 18 may be included in the plasma processing apparatus 1, in place of the substrate support 11 and the lifter 50 shown in FIG. 13 or FIG. 14. With the plasma processing apparatus 1 including the substrate support 11 and the lifter 50 shown in FIG. 17 or FIG. 18 as well, the method MT can be implemented as with the plasma processing apparatus 1 including the substrate support 11 and the lifter 50 shown in FIG. 13 or FIG. 14. The substrate supports 11 and the lifters 50 shown in FIGS. 17 and 18 will now be described focusing on their differences from the substrate supports 11 and the lifters 50 shown in FIGS. 13 and 14.

As shown in FIGS. 17 and 18, the lifters 50 each further include a protective member 51p. The protective member 51p is a ring extending circumferentially about the central axis of the substrate support 11. The protective member 51p is conductive and is mounted on the conductive ring 51 to protect the conductive ring 51 from plasma. The protective member 51p is formed from a plasma-resistant material. The protective member 51p may be formed from the same material as the edge ring UR. In this embodiment, the edge ring UR is electrically coupled to the conductive ring 51 with the protective member 51p between them while the conductive ring 51 is supporting the edge ring UR.

In each of the embodiments shown in FIGS. 17 and 18, the plasma processing apparatus 1 further includes a lifter 70. The lifter 70 includes multiple lift pins 71 and an actuator 72. The rods 52 in the lifter 50 shown in FIG. 17 and the lift pins 71 shown in FIG. 18 may be arranged alternately in the circumferential direction about the central axis of the substrate support 11. The multiple rods 52 and the multiple lift pins 71 may be arranged at equal intervals.

The multiple lift pins 71 can be placed into the respective through-holes extending in the vertical direction through the conductive ring 51 and the protective member 51p. The actuator 72 moves the lift pins 71 vertically under control by the controller 2. When the lifter 70 retracts the lift pins 71 downward to cause the lift pins 71 to have their upper ends out of contact with the edge ring UR, the first state described above is established. When the lifter 70 raises the edge ring UR upward from the protective member 51p with the lift pins 71, the second state described above is established. The lifter 70 thus serves as the switch 80.

In response to the plasma processing specified in the recipe being plasma processing to be performed on the substrate W on the substrate support 11 as described above, the controller 2 controls the lifter 70, or the switch 80, to establish the first state described above in step STb. In this case, the controller 2 controls the components of the plasma processing apparatus 1 to perform the plasma processing on the substrate W in step STd.

In response to the plasma processing specified in the recipe being plasma cleaning of the chamber 10, the controller 2 controls the lifter 70, or specifically, the switch 80, to establish the second state in step STb. In this case, the controller 2 controls the components of the plasma processing apparatus 1 to perform the plasma cleaning in step STd. The controller 2 also controls the lifter 70 to position the edge ring UR higher when the plasma cleaning is performed than when the plasma processing is performed on the substrate W. This allows active species in the plasma to be fed into a space between the lower surface of the edge ring UR and the upper surface (the ring support surface or the upper surface of the edge ring LR) facing the lower surface of the edge ring UR, thus facilitating removal of the deposit described above.

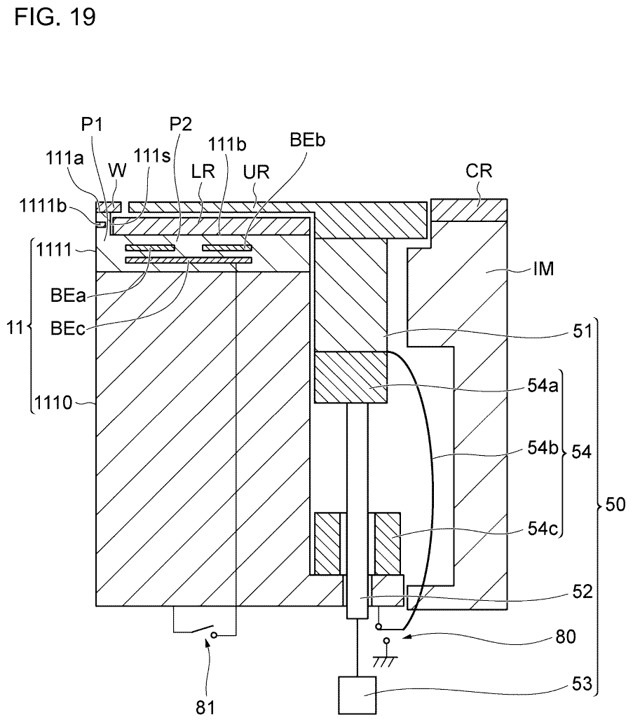

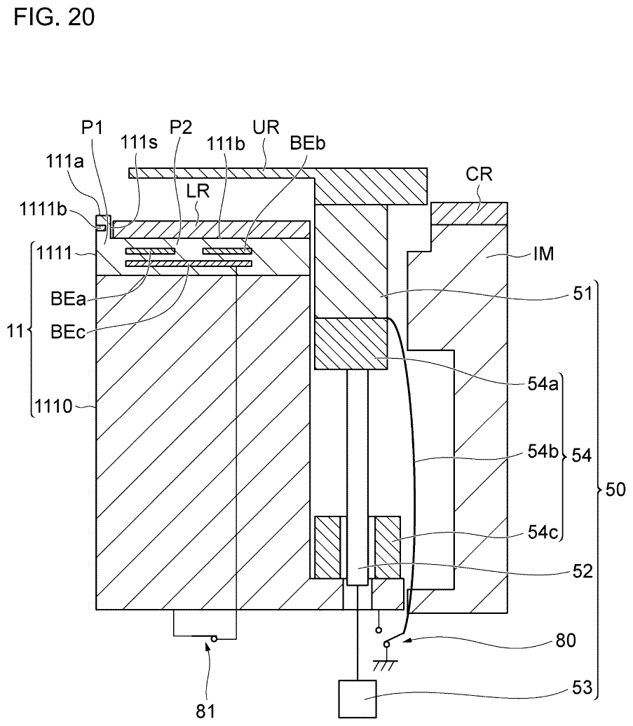

FIGS. 19 and 20 will now be referred to. FIGS. 19 and 20 are each a diagram of a substrate support and a lifter in still another exemplary embodiment. The substrate support 11 and the lifter 50 shown in FIG. 19 or FIG. 20 may be included in the plasma processing apparatus 1, in place of the substrate support 11 and the lifter 50 shown in FIG. 13 or FIG. 14. With the plasma processing apparatus 1 including the substrate support 11 and the lifter 50 shown in FIG. 19 or FIG. 20 as well, the method MT can be implemented as with the plasma processing apparatus 1 including the substrate support 11 and the lifter 50 shown in FIG. 13 or FIG. 14. The substrate supports 11 and the lifters 50 shown in FIGS. 19 and 20 will now be described focusing on their differences from the substrate supports 11 and the lifters 50 shown in FIGS. 13 and 14.

As shown in FIGS. 19 and 20, the ESCs 1111 each include an electrode BEc below the edge ring UR, or more specifically, incorporated in the second portion P2. The electrode BEc is electrically coupled to the base 1110 with a switching element 81.

When the plasma processing is performed on the substrate W in step STd, the controller 2 may set the switching element 81 to be OFF (open) to electrically disconnect the electrode BEc from the base 1110. When the plasma processing is performed on the substrate W in step STd, the controller 2 controls the switch 80 (switching element) to establish the first state described above.

When the plasma cleaning of the chamber 10 is performed in step STd, the controller 2 controls the lifter 50 to position the edge ring UR higher than when the plasma processing described above is performed on the substrate W. When the plasma cleaning of the chamber 10 is performed in step STd, the controller 2 sets the switching element 81 to be ON (closed) to electrically couple the electrode BEc and the base 1110. When the plasma cleaning of the chamber 10 is performed in step STd, the controller 2 controls the switch 80 (switching element) to establish the second state described above and to couple the edge ring UR to the ground through the conductive ring 51. This forms an RF electric field corresponding to the source RF signal, to the bias RF signal, or to both the signals between the electrode BEc and the edge ring UR. This generates plasma from the cleaning gas in a space between the lower surface of the edge ring UR and the upper surface (the ring support surface or the upper surface of the edge ring LR) facing the lower surface of the edge ring UR. This locally generates plasma for removing a deposit in the space. The structures in the embodiments shown in FIGS. 19 and 20 may be included in each of the embodiments in FIGS. 15 and 16.

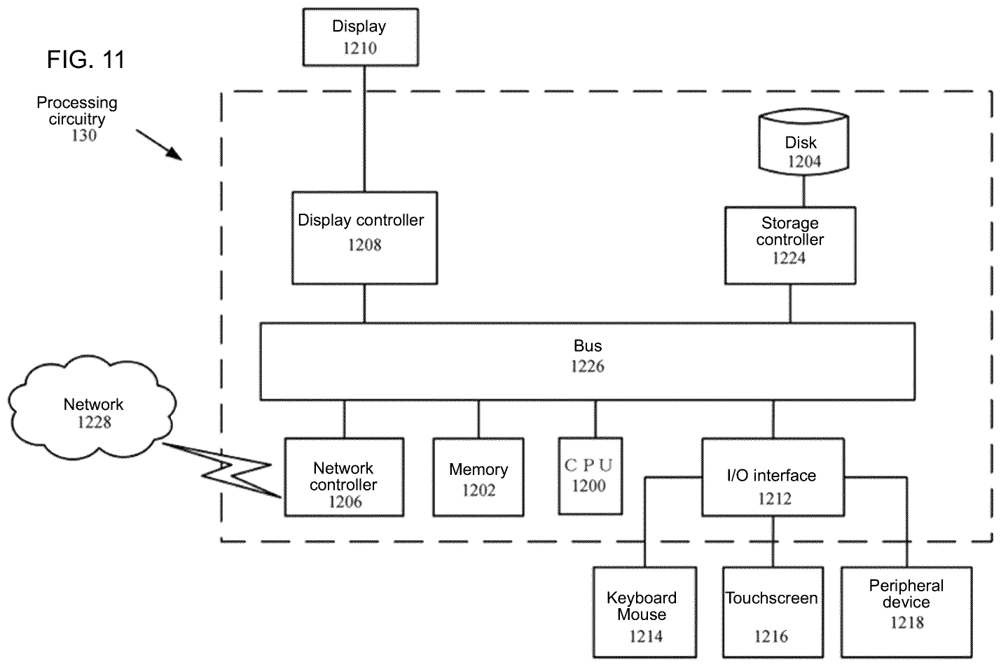

Example processing circuitry that may be used as one or more processing circuits will now be described. Examples of the processing circuitry include the controller 2 in the plasma processing apparatus 1 and the controller MC in the substrate processing system PS. FIG. 11 is a block diagram of processing circuitry for performing computer-based operations described herein. FIG. 11 illustrates processing circuitry 130 that may be used to control any computer-based control processes. The descriptions or blocks in the flowcharts represent modules, segments, or portions of a code including one or more executable instructions for implementing specific logical functions or steps in the processes. Alternate implementations are included within the scope of the exemplary embodiments of the disclosure in which functions can be executed in an order different from the order shown or discussed, including substantially concurrently or in reverse order, depending on the functionality involved, as will be understood by those skilled in the art. The various elements, features, and processes described herein may be used independently of one another or may be combined in various ways. All possible combinations and sub-combinations are intended to fall within the scope of the disclosure.

In FIG. 11, the processing circuitry 130 includes a CPU 1200 that performs one or more of control processes described above or described below. The processing data and instructions may be stored in a memory 1202. These processing data and instructions may be stored in a storage medium disk 1204, such as an HDD or a portable storage medium, or may be stored remotely. Further, the techniques described in the scope of the claims are not limited to the form of the computer-readable media in which instructions for the inventive processes are stored. For example, the instructions may be stored in any other information processing device such as a compact disc (CD), a digital versatile disc (DVD), a flash memory, a RAM, a ROM, a programmable ROM (PROM), an erasable programmable ROM (EPROM), an electrically erasable programmable (EEPROM), a hard disk drive, or at least one of a server or a computer with which the processing circuitry 130 communicates.

The techniques described in the scope of the claims may be provided as a utility application, a background daemon, a component of an operating system, or a combination of these, or may be implemented in cooperation with the CPU 1200 and an operating system such as Microsoft Windows (registered trademark), UNIX (registered trademark), Solaris (registered trademark), LINUX (registered trademark), Apple MAC-OS, and other systems known to those skilled in the art.

The hardware elements to achieve the processing circuitry 130 can be implemented by various circuit elements. Further, each of the functions of the above described embodiments may be implemented by circuitry, which includes one or more processing circuits. As shown in FIG. 11, the processing circuitry includes a specifically programmed processor, for example, a processor (CPU) 1200. The processing circuitry also includes devices such as an application-specific integrated circuit (ASIC) or known circuit components to perform the described functions.

In FIG. 11, the processing circuitry 130 includes the CPU 1200 that performs the processes described above. The processing circuitry 130 may be a general-purpose computer or a specific dedicated machine. In one or more embodiments of the present disclosure, the processing circuitry 130 functions as a dedicated machine when the processor 1200 is programmed to control the components of the plasma processing apparatus 1, such as the gas supply 20, the power supply 30, the lifter 50, and the switch 80.

Alternatively, or additionally, the CPU 1200 may be implemented on a field-programmable gate array (FPGA), an ASIC, a programmable logic device (PLD) or using a discrete logic circuit, as will be understood by those skilled in the art. Further, the CPU 1200 may be implemented as multiple processors cooperatively working in parallel to perform the instructions of the processes in the embodiments of the disclosure described above.

The processing circuitry 130 in FIG. 11 also includes a network controller 1206, such as an Intel Ethernet PRO network interface card from Intel Corporation of America, for connecting to the network 1228. As can be understood, the network 1228 may be a public network such as the Internet, a private network such as a LAN or wide area network (WAN), or any combination of these, or may also include a sub-network such as a public switched telephone network (PSTN) or an integrated services digital network (ISDN). The network 1228 may also be wired, such as an Ethernet network, or may be wireless such as a cellular network including Enhanced Data GSM Environment (EDGE), 3G, and 4G wireless cellular systems. The wireless network may also be Wi-Fi, Bluetooth (registered trademark), or in any other known wireless communication form.

The processing circuitry 130 further includes a display controller 1208, such as a graphics card or graphics adaptor for interfacing with a display 1210, such as a monitor. A general purpose I/O interface 1212 interfaces with at least one of a keyboard or a mouse 1214 as well as with a touchscreen 1216 integral with or separate from the display 1210. The general purpose I/O interface is also connected to various peripheral devices 1218, such as a printer and a scanner. The general-purpose I/O interface is also connected to various peripheral devices 1218, such as a printer and a scanner.

The storage controller 1224 connects the storage medium disk 1204 with a communication bus 1226, which may be an Industry Standard Architecture (ISA), Extended Industry Standard Architecture (EISA), Video Electronics Standards Association (VESA) Local Bus, or Peripheral Component Interconnect (PCI) for interconnecting all the components of the processing circuitry 130. The general features and functions of the display 1210, at least one of the keyboard or the mouse 1214, the display controller 1208, the storage controller 1224, a network controller 1206, a sound controller 1220, and a general purpose I/O interface 1212 will not be described herein for simplicity.

The exemplary circuit elements described in the context of the disclosure may be replaced with other elements and structured differently from the examples provided herein. Further, circuitry that performs the features described herein may be implemented by multiple circuit units (e.g., chips) or may incorporate these features into circuitry of a single chipset.

The functions and features described herein may also be implemented by various distributed components of the system. For example, one or more processors may perform the functions of the system. In this case, the processors may be distributed across multiple components communicating in a network. The distributed components may include one or more clients and server machines that can share processing, in addition to various human interfaces and communication devices (e.g., display monitors, smartphones, tablets, and personal digital assistants or PDAs). The network may be a private network, such as a LAN or WAN, or may be a public network, such as the Internet. Input into the system may be received directly by a user, or may be received remotely either in real time or as a batch process. Additionally, some implementations may be performed on modules or hardware not identical to those described. Accordingly, other implementations are within the scope that may be claimed.

Although the exemplary embodiments have been described above, the embodiments are not restrictive, and various additions, omissions, substitutions, and changes may be made. The components in the different exemplary embodiments may be combined to form another exemplary embodiment.

For example, any of the containers FUa to FUd described above may be used as the stocker module RSM.

The exemplary embodiments according to the disclosure have been described by way of example, and various changes may be made without departing from the scope and spirit of the disclosure. The exemplary embodiments described above are thus not restrictive, and the true scope and spirit of the disclosure are defined by the appended claims.

### REFERENCE SIGNS LIST

1 Plasma processing apparatus
2 Controller
10 Chamber
11 Substrate support
12 Plasma generator
1110 Base
1111 Electrostatic chuck (ESC)
50 Lifter
51 Conductive ring
52 Rod
53 Actuator
54 Connector
80 Switch

1. A plasma processing apparatus, comprising:
a chamber;
a substrate support in the chamber, the substrate support including:
a base, and
an electrostatic chuck on the base;
a plasma generator including a radio-frequency power supply, the plasma generator being configured to generate plasma in the chamber;
a bias power supply configured to generate an electrical bias to draw ions from the plasma into a substrate that is disposed on the substrate support,
wherein at least one of the bias power supply or the radio-frequency power supply being electrically coupled to the base;
an edge ring surrounding the substrate on the substrate support, the edge ring being conductive;
a lifter configured to raise and lower the edge ring, the lifter including:
a conductive ring electrically coupled to the edge ring while supporting the edge ring placed on the conductive ring,
a rod extending in a vertical direction below the conductive ring,
an actuator configured to raise and lower the edge ring with the rod and the conductive ring, and
a connector electrically coupling the conductive ring and the base;
a switch configured to change between a first state in which the edge ring and the base are electrically coupled to each other and a second state in which the edge ring and the base are electrically disconnected from each other; and
a controller having a processor and a memory with a computer readable program stored therein that upon execution of the computer readable program by the processor, the controller being configured to control the switch to switch between the first state and the second state.

2. The plasma processing apparatus according to claim 1, wherein
the lifter is the switch and the lifter is configured to change to the second state by lowering the conductive ring with the actuator to separate the conductive ring from the edge ring.

3. The plasma processing apparatus according to claim 1, wherein
the switch includes a switching element connected between the connector and the conductive ring or between the connector and the base.

4. The plasma processing apparatus according to claim 1, wherein
the switch includes a second lifter configured to raise the edge ring from the conductive ring to change to the second state.

5. The plasma processing apparatus according to claim 1, wherein
the controller is configured to:
control the switch to change to the first state in response to plasma processing being performed on the substrate disposed on the substrate support, and
control the switch to change to the second state in response to plasma cleaning of the chamber being performed.

6. The plasma processing apparatus according to claim 3, wherein
the controller is configured to:
control the switch to change to the first state in response to plasma processing being performed on the substrate disposed on the substrate support,
control the switch to change to the second state in response to plasma cleaning of the chamber being performed, and
control the lifter to position the edge ring higher when the plasma cleaning is performed than when the plasma processing is performed on the substrate.

7. The plasma processing apparatus according to claim 6, wherein
the edge ring includes an inner circumferential portion and an outer circumferential portion, and the outer circumferential portion is located on the conductive ring and the edge ring is being supported on the conductive ring, and
the outer circumferential portion has a vertical length to cover the conductive ring from a space above the substrate support during the plasma cleaning.

8. The plasma processing apparatus according to claim 6, wherein
the lifter further includes a film covering a surface of the conductive ring to protect the conductive ring from the plasma.

9. The plasma processing apparatus according to claim 6, wherein
the electrostatic chuck includes, below the edge ring, an electrode incorporated in the electrostatic chuck,
the plasma processing apparatus further comprises a second switching element electrically coupled between the base and the electrode, and
the controller is configured to:
control the switching element included in the switch to electrically disconnect the conductive ring from the base during the plasma cleaning to couple the conductive ring to a ground, and
control the second switching element to electrically couple the electrode and the base to each other during the plasma cleaning.

10. The plasma processing apparatus according to claim 4, wherein
the lifter is conductive and further includes a protective member on the conductive ring, and
the controller is configured to:
control the switch to change to the first state in response to plasma processing being performed on the substrate on the substrate support,
control the switch to change to the second state in response to plasma cleaning of the chamber being performed, and
control the second lifter to position the edge ring higher when the plasma cleaning is performed than when the plasma processing is performed on the substrate and position the edge ring above and spaced from the conductive ring and the protective member.

11. The plasma processing apparatus according to claim 10, wherein
the protective member comprises a same material as the edge ring.

12. The plasma processing apparatus according to claim 1, wherein
the controller is configured to:
cause the switch to change to the first state to perform plasma etching specified in a recipe to form a recess on the substrate on the substrate support,
cause the switch to change to the second state to perform ashing specified in the recipe to remove a deposit on the substrate, and
cause the switch to change to the first state after the ashing to perform plasma etching specified in the recipe to increase a depth of the recess.

13. The plasma processing apparatus according to claim 1, wherein
the controller is configured to:
cause the switch to change to, with the edge ring placed on the substrate support, the second state to perform first plasma cleaning of the chamber specified in a recipe,
cause the switch to change to, with the edge ring placed on the substrate support, the first state to perform second plasma cleaning of the chamber specified in the recipe, and
cause the switch to change to, after the edge ring on the substrate support is replaced, the second state to perform seasoning of the chamber specified in the recipe.

14. The plasma processing apparatus according to claim 1, further comprising:
a sensor configured to measure an amount of a deposit on the edge ring,
wherein the controller is configured to:
control the switch to change to the first state to perform plasma cleaning of the chamber specified in a recipe to remove the deposit, and
control the switch to change to the second state in response to the amount of the deposit measured by the sensor during the plasma cleaning reaching or falling below a threshold.

15. A plasma processing method implementable using the plasma processing apparatus according to claim 1, the method comprising:
reading, with the controller, a recipe;
controlling the switch based on the recipe; and
performing plasma processing based on the recipe.

16. The plasma processing method according to claim 15, wherein
controlling the switch includes:
controlling the switch to change to the first state in response to the plasma processing specified in the recipe being plasma processing to be performed on the substrate on the substrate support, and
controlling the switch to change to the second state in response to the plasma processing specified in the recipe being plasma cleaning of the chamber.

17. The plasma processing method according to claim 16, wherein
the edge ring is positioned higher when the plasma cleaning is performed than when the plasma processing is performed on the substrate.

18. The plasma processing method according to claim 17, wherein
the conductive ring is electrically disconnected from the base during the plasma cleaning and is coupled to a ground, and
during the plasma cleaning, an electrode incorporated in the electrostatic chuck below the edge ring and the base are electrically coupled to each other with a switching element.

19. The plasma processing method according to claim 15, wherein
controlling the switch includes causing the switch to change to the first state to form a recess on the substrate on the substrate support, and performing the plasma processing includes performing plasma etching specified in the recipe,
controlling the switch includes causing the switch to change to the second state to remove a deposit on the substrate, and performing the plasma processing includes performing ashing specified in the recipe, and
controlling the switch includes causing the switch to change to the first state after the ashing to increase a depth of the recess, and performing the plasma processing includes performing plasma etching specified in the recipe.

20. The plasma processing method according to claim 15, wherein
controlling the switch includes causing the switch to change to the second state with the edge ring placed on the substrate support, and performing the plasma processing includes performing first plasma cleaning of the chamber specified in the recipe,
controlling the switch includes causing the switch to change to the first state with the edge ring placed on the substrate support, and performing the plasma processing includes performing second plasma cleaning of the chamber specified in the recipe, and
controlling the switch includes causing the switch to change to the second state after the edge ring on the substrate support is replaced, and performing the plasma processing includes performing seasoning of the chamber specified in the recipe.

21. The plasma processing method according to claim 15, wherein
the plasma processing apparatus further comprises a sensor configured to measure an amount of a deposit on the edge ring,
controlling the switch includes causing the switch to change to the first state to remove the deposit, and performing the plasma processing includes performing plasma cleaning of the chamber specified in the recipe, and
controlling the switch includes controlling the switch to change to the second state in response to the amount of the deposit measured by the sensor during the plasma cleaning reaching or falling below a threshold.
